(19) United States
(12) Patent Application Publication
(10) Pub. No.: US 2008/0205012 A1
(43) Pub. Date: Aug. 28, 2008

(54) CHIP CARD MODULE AND METHOD OF PRODUCING A CHIP CARD MODULE

(75) Inventors: ERIK HEINEMANN, Regensburg (DE); Andreas Mueller-Hipper, Regensburg (DE); Frank Pueschner, Kehlheim (DE); Thomas Spoetti, Regensburg (DE)

Correspondence Address: DICKSTEIN SHAPIRO LLP, 1177 AVENUE OF THE AMERICAS 6TH AVENUE, NEW YORK, NY, 10036-2714, US

(73) Assignee: Infineon Technologies AG, Neubiberg (DE)

(21) Appl. No.: 11/963,468

(22) Filed: Dec. 21, 2007

(30) Foreign Application Priority Data
Dec. 21, 2006 (DE) 10 2006 060719.8

(51) Int. Cl. H05K 7/02; H05K 3/30

(52) U.S. Cl. 361/767; 29/841

(57) ABSTRACT

A chip card module including a substrate and also conductor patterns, which are applied on at least one side of the substrate without any adhesive. A chip is arranged on one side of the substrate and connected in an electrically conducting manner to the conductor patterns. A mold cap encapsulates at least part of the chip and of the conductor patterns. The method of producing such a chip card module includes providing a substrate, applying conductor patterns to at least one side of the substrate without any adhesive, mounting a chip on one side of the substrate, connecting the chip to the conductor patterns, and applying a molding compound on the substrate, so that at least part of the chip and of the conductor patterns is covered.

### CROSS-REFERENCE TO RELATED APPLICATION

This application claims priority to German Patent Application Serial No. 102006060719.8, which was filed Dec. 21, 2006, and is incorporated herein by reference in its entirety.

### FIELD OF THE INVENTION

The invention relates to a chip card module and to a method of producing such a chip card module.

### BACKGROUND OF THE INVENTION

Chip cards are used for many applications. Typically, a chip card comprises a card body into which a chip card module with a chip has been introduced. Access to the chip can take place by way of a contact-based interface. In this case, the chip card module usually comprises contact areas which are accessible after the chip card module has been fitted into the card body.

A chip card module may also be formed in such a way that access to the chip takes place by way of a contactless interface, for example by means of an electromagnetic field.

The chip card module usually comprises a substrate, for example epoxy resin, epoxy for short. In the case of conventional chip card modules, conductor patterns of copper foil are laminated on the substrate by means of an adhesive. The thickness of the laminated-on foil also has an effect on the thickness of the chip card module. The electrical connection between contact areas on one side of the substrate and on the other side, on which the chip is provided, may take place for example by way of plated-through holes.

The production of a substrate with conductor patterns adhesively attached in such a way, in particular in the case of a multilayered metallized and plated-through configuration, is cost-intensive.

For security applications, for example access authorization cards or chip card modules for passports, a high level of reliability and robustness of the chip card modules is required. Aggressive or careless handling of the chip card, which goes hand in hand with the increasingly broad applications of chip cards, necessitates robust chip card modules.

### SUMMARY OF THE INVENTION

A chip card module that comprises a substrate with a first side and a second side is provided. Also provided are conductor patterns, which are applied on at least one side of the substrate without any adhesive. A chip is arranged on one side of the substrate and connected in an electrically conducting manner to the conductor patterns. A mold cap, which encapsulates at least part of the chip and of the conductor patterns, is also provided.

### BRIEF DESCRIPTION OF THE DRAWINGS

Exemplary embodiments of the invention are explained below with reference to the drawing, in which:

FIG. 1 shows a schematic representation of an exemplary embodiment of the chip card module,

FIG. 2 shows a flow diagram which illustrates the production of an exemplary embodiment of the chip card module,

FIG. 3 shows a schematic representation of an exemplary embodiment of a chip card module,

FIG. 4 shows a schematic representation of a further exemplary embodiment of a chip card module,

FIG. 5 shows a schematic representation of an exemplary embodiment of a chip card module,

FIG. 6 shows a schematic representation of a further exemplary embodiment of a chip card module, and

FIG. 7 shows a schematic representation of a further exemplary embodiment of a chip card module.

### DETAILED DESCRIPTION OF THE INVENTION

In FIG. 1, an exemplary embodiment of a chip card module is schematically represented. The chip card module comprises a substrate 1 with a first side 11 and a second side 12. Also provided are conductor patterns 3, 4, which are applied on both sides 11, 12 of the substrate 3, 4 without any adhesive. The conductor patterns 3, 4 comprise a starter layer 101 and an electroplated layer 102. The conductor patterns 3, 4 on both sides of the substrate 1 are also connected in an electrically conducting manner, in a further exemplary embodiment, conductor patterns may only be provided on one side of the substrate.

In the exemplary embodiment represented, a chip 2 is arranged on one side of the substrate 1 and connected in an electrically conducting manner to the conductor patterns 3, 4. For the fixing of the chip 2, a chip adhesive 7 is provided between the mutually facing sides of the chip 2 and of the substrate 1. Also provided is a mold cap 8, which encapsulates the chip 2 and at least part of the conductor patterns 3.

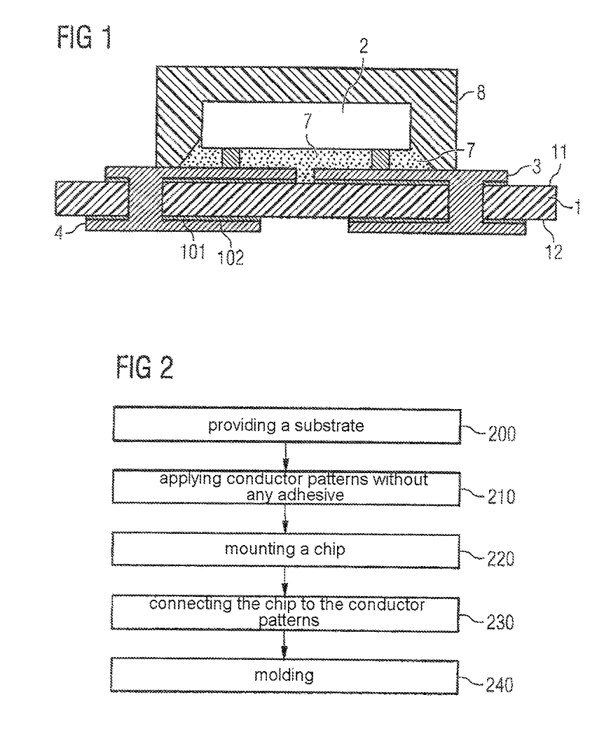

The exemplary embodiment represented in FIG. 2 illustrates the production of an exemplary embodiment of such a chip card module on the basis of a flow diagram with five blocks 200, 210, 220, 230, 240, which represent the main method steps.

It is first envisaged to provide the substrate 1 with the first side 11 and the second side 12, as block 200 shows. Conductor patterns 3, 4 are applied to at least one side of the substrate 1 without any adhesive, as block 210 illustrates. The chip 2 is mounted on one side of the substrate 1 and connected to the conductor patterns 3, 4, as blocks 220 and 230 illustrate. Furthermore, a molding compound is applied to the substrate 1, so that at least part of the chip 2 and of the conductor patterns 3, 4 is covered, which block 240 illustrates. The method steps are explained in detail below.

As represented by block 200, firstly the substrate 1 is provided. The substrate 1 is formed from a flexible material. For exemplary embodiments with a contact-based interface, polyethylene terephthalate (PET), polyether imides (PEI) or paper are particularly suitable for example. For exemplary embodiments with a contactless interface, polyimides (PI) and paper are used.

Block 210 represents the application of the conductor patterns 3, 4. For this purpose, a starter layer 101 is applied to at least one side 11, 12 of the substrate 1. This may take place by the so-called substractive technique. In an exemplary embodiment, a sputter layer, preferably with conducting particles, for example copper particles, is applied to the substrate 1. A sputter layer may be so thin that its thickness is in the Angstrom range. In the exemplary embodiments, after application of the sputter layer 101, a subsequent galvanic reinforcement of this layer 102 takes place. In an exemplary embodiment, this layer 102 is formed as a copper layer which has a thickness of from 2 μm to 3 μm. In a further exemplary embodiment, the layer 102 is about 1.3 μm thick. In another exemplary embodiment, the copper layer has a thickness of about 0.8 μm. In a further exemplary embodiment, the copper layer has a thickness of about 0.5 μm. The electroplating takes place in a metallization bath.

In a further step, in an exemplary embodiment holes are made in the substrate 1 for plated-through holes 5. This would take place, for example, by means of lasering or punching. In an exemplary embodiment, the introduction of the holes takes place after the application of the starter layer 101.

In a further step, the electroplated layer 102 is reinforced by further electroplating again by a layer 303, for example to a thickness of from 10 μm to 15 μm.

The patterning takes place by etching this layer by means of a photo technique. Subsequently, in an exemplary embodiment, a nickel-gold layer is applied.

In a further exemplary embodiment, the patterning takes place after the first subsequent reinforcement of the sputter layer 101. This is followed by the further reinforcement of this layer 102 to the thickness of the conductor patterns 3.

In a further exemplary embodiment, the sputter layer 101 is patterned before the subsequent reinforcement.

By controlling the electroplating process, in particular with respect to the duration and number of electroplating steps, the thickness of the conductor patterns 3 is determined. This makes it possible to form thin conductor patterns 3, the thickness of which may be less than films that are adhesively attached in a conventional manner, with a thickness of at least 18 μm and usually 35 μm. For example, conductor pattern thicknesses in the range of just a few micrometers can also be formed by electroplating. However, greater layer thickness can also be achieved by electroplating. The number of electroplating steps is variable.

Alternatively, the printed circuit board, that is to say the substrate 1 with the conductor patterns 3, 4, may be produced for an exemplary embodiment in which a metal foil, for example a copper foil, is applied to the substrate 1 without any adhesive, which is referred to as “copper clad”. In this case, epoxy resin is suitable as the substrate 1. This layer is patterned by means of a photo technique and galvanically treated. The galvanic treatment takes place for example with nickel, Ni for short, or nickel gold, NiAu for short.

In the case of a further exemplary embodiment, a patterned starter layer 101 is applied to the substrate 1, by using the so-called additive technique. In this case, conductive ink is printed onto the substrate 1. The patterning takes place during the printing process. In this case too, a subsequent galvanic reinforcement and subsequent galvanic treatment are also provided, taking place in the same way as in the case of the electroplating of the sputter layer. Nickel and nickel gold are suitable for this.

Blocks 220 and 230 represent the chip module steps in which the chip 2 is mounted on the printed circuit board 1, 3, 4.

Firstly, the chip adhesive 7 is applied to the substrate 1. Bumps 6 are applied to the chip terminals 21. Then, the chip 2 is pressed with its terminals facing the substrate 1 into the chip adhesive 7, so that the bumps 6 displace the chip adhesive 7 and touch the conductor patterns 3, in order to establish the electrically conducting contact. It should be noted that, in the case of this exemplary embodiment, the steps represented in blocks 220 and 230 coincide. Apart from the contacting by the flip-chip technique described above, other connecting techniques are also suitable.

Alternatively, it is also possible first to connect the chip 2 to the conductor patterns 3 by way of the bumps 6, and then to apply the chip adhesive 7 from the edge region of the chip 2, so that said adhesive also draws itself under the chip 2. However, this way of fixing the chip 2 is more cost-intensive and time-intensive than that described above.

Subsequently, in the injection compression molding process, the compression molding compound, that is to say the molding compound, is applied to the chip 2 and the substrate 1 with the conductor patterns 3, in order to encapsulate the chip 2. For this purpose, the heated molding compound is forced into a compression mold, which encloses the chip 2 and predetermines the shape of the mold cap 8. After cooling, the mold cap 8 is formed.

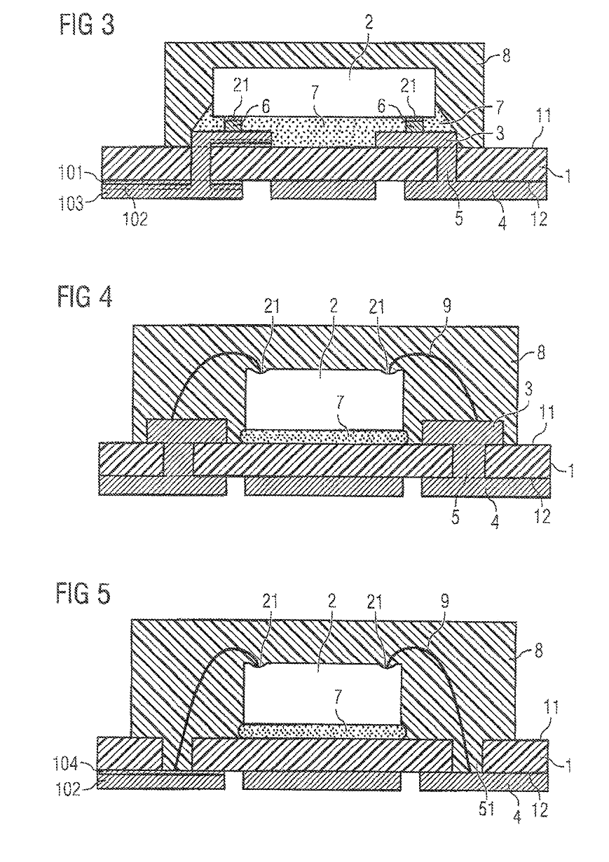

FIG. 3 shows a schematic representation of an exemplary embodiment of a chip card module with a contact-based interface, which can be produced by the method described above.

The chip card module comprises a substrate 1 with a first side 11, which is the upper side in FIG. 1, and a second side 12, which is the lower side in FIG. 1. On the first side 11 of the substrate 1, conductor patterns 3 are applied. The chip 2, which has chip contacts 21, is connected in an electrically conducting manner to the conductor patterns 3 on the first side 11. The connection takes place by way of contact elements, known as bumps 6, which are positioned between the chip contacts 21 and the conductor patterns 3. The chip 2 is fixed by a chip adhesive 7, which is introduced between the chip 2 and the substrate 1 with the conductor patterns 3. Side edge regions of the chip 2 are also touched by the chip adhesive 7.

On the second side 12 of the substrate 1, further conductor patterns are applied, forming contact areas 4 by way of which the chip 2 can be accessed. The conductor patterns 3 on the first side 11 are connected in a conducting manner to the contact areas 4 on the second side 12 by way of plated-through holes 5. The plated-through holes 5 are clearances right through the substrate 1, the walls of which are at least lined with conducting material. An alternative configuration of the plated-through holes 5 comprises clearances filled with conducting material.

The layers of the conductor patterns 3, 4 are represented in FIG. 3. A starter layer 101 is arranged adjacent the substrate 1. The starter layer may be sputtered, printed or laminated. On the starter layer 101, a first electroplated layer 102 is applied for reinforcement. A second electroplated layer 103, which has been applied in a further electroplating step, is applied on the first electrode layer 102.

Both the chip 2 and the conductor patterns 3 on the first side 11 of the substrate 1 are encapsulated with a mold cap 8.

FIG. 4 shows a schematic representation of a further exemplary embodiment of a chip card module which comprises a contact-based interface.

The chip card module comprises a substrate 1 with a first side 11 and a second side 12. On the first side 11 of the substrate 1, conductor patterns 3 are applied. On the second side 12, contact areas 4 are applied, connected by way of printed-through holes to the conductor patterns 3 on the first side 11.

The chip 2 is fixed on the first side 11 of the substrate 1 by means of chip adhesive 7. Provided on the side of the chip 2 that is facing away from the substrate 1 are chip contacts 21, which are connected in an electrical conducting manner to the conductor patterns 3 by way of bonding wires 9. This type of contacting is also referred to as wire bonding.

Not only the chip 2 but also the bonding wires 9 and the conductor patterns 3 on the first side 11 of the substrate 1 are encapsulated with a mold cap 8.

The production of this exemplary embodiment differs from the production of the exemplary embodiment described above with respect to the chip assembly. The production of the printed circuit board takes place as described.

The chip 2 is adhesively attached onto the printed circuit board 1, 3, 4 and the chip contacts 21 and the conductor patterns 3 are bonded. This is followed by the application of the mold cap 8 by means of a compression molding process.

FIG. 5 shows a schematic representation of an exemplary embodiment of a chip card module which comprises a contact-based interface.

To avoid repetition, features which coincide with the previous exemplary embodiment are not described. Only the differences with respect to the previous exemplary embodiment are discussed below.

Instead of the plated-through holes, holes 51 between the first side 11 and the second side 12 that are covered at one end by the contact areas 4 on the second side 12 are provided.

The chip contacts 21 are connected to the side of the contact areas 4 that is facing the substrate 1 by way of bonding wires 9, in that the bonding wires 9 are led from the chip contacts 21 through the holes 51 to the contact areas 4.

For the production of this exemplary embodiment, a suitable procedure is firstly to introduce the holes 51 into the substrate 1, for example by punching or lasering, and then to laminate a metal foil 104, for example a copper foil, on the second side 12 of the substrate 1 without any adhesive. Further production, comprising galvanic treatment for depositing an electroplated layer 102, chip assembly and encapsulation, takes place in the way already described.

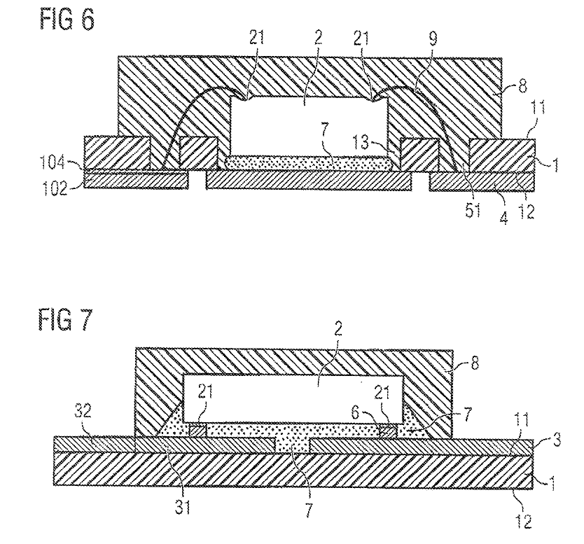

FIG. 6 shows a schematic representation of an exemplary embodiment of the chip card module which differs from the previous one in that a clearance 13 into which the chip 2 is introduced is provided in the substrate 1. The chip 2 is mounted on the back side of the contact areas 4 by means of an adhesive 7.

FIG. 7 shows a schematic representation of a further exemplary embodiment of a chip card module, which can be contacted by way of a contactless interface.

The chip card module comprises a substrate 1 with a first side 11 and a second side 12. On the first side 11 of the substrate 1, conductor patterns 3 are applied. The chip 2 is connected in an electrically conducting manner to the conductor patterns 3 on the first side 11 by way of contact elements, known as bumps 6. The chip 2 is fixed by a chip adhesive 7, which is positioned between the chip 2 and the substrate 1 or the conductor patterns 3.

Both the chip 2 and regions 31 of the conductor patterns 3 on the first side 11 of the substrate 1 are encapsulated with a mold cap 8. Other regions 32 of the conductor patterns 3 are not encapsulated and serve during the fitting of the chip card module into the chip card as contact regions for a coil that is to be contacted. In one exemplary embodiment, such a coil may run in the card body. In an alternative exemplary embodiment, a coil is formed by the conductor patterns. In such a case, no contact regions that are accessible are provided. Rather, the coil is also encapsulated.

The production of this exemplary embodiment can take place in the way already described. However, the application of conductor patterns to the second side 12 of the substrate 1 and the formation of holes or plated-through holes are not envisaged.

It should be noted that the features of the exemplary embodiments described can be combined. For instance, one exemplary element concerns a dual-mode chip card module, which comprises both a contact-based interface and a contactless interface.

An advantage of the described ways of conducting the method of production is that sputtering and printing can be carried out on many materials, so that the properties of the chip card module can be specifically influenced by suitable material selection. Consequently, more materials are available than in the case of conventional production.

In particular as a result of the sputtering technology and the possibility of selecting flexible substrate materials, the mechanical properties of the chip card module can be selectively controlled.

The chip card module is on the one hand flexible, as a result of the substrate, and on the other hand nevertheless very robust, as a result of the mold cap. These properties prevent damage to the chip card module under flexural loads of the chip card in which the module is later used. In particular, the mold cap decisively increases the resistance of the chip card module and is particularly of advantage for high quality requirements. By matching the materials of the mold cap and the substrate, very good adhesive bonding of the mold cap can be achieved. This is of advantage in particular in applications in which thermal or climatic fluctuations occur.

Such a form of a chip card module is both thin and robust.

It should be noted that the expression “chip card module” does not entail any restriction to the use of such modules in chip cards. Other types of use, in particular for passports, are also conceivable.

One form of the chip card module envisages a flexible substrate, which may be formed for example from polyethylene terephthalate, polyether imide, polyimide or paper. The combination of a flexural substrate and a protective mold cap has the effect of forming a module which is both flexible and robust and can additionally be produced at low cost.

The conductor patterns comprise a starter layer, which is for example a sputter layer that can be applied without any adhesive. A further configuration of the conductor patterns comprises a metal foil layer that can be applied without any adhesive. Dispensing with the adhesive layer reduces the thickness of the chip card module. Such layers are patterned by etching.

A further configuration of the conductor patterns comprises a printed layer as the starter layer, the patterning of which takes place in a low-cost and process-effective way during the printing.

One configuration of the conductor patterns comprises an electroplated layer, which can be applied to one of the aforementioned layers. The thickness of this layer can be controlled in the production process.

One configuration of the chip card module comprises a contact-based interface with contact areas which are applied on the side of the substrate that is facing away from the chip. A further configuration alternatively or additionally comprises a contactless interface or contacts for the connection of a contactless interface, in order to make contactless access to the chip possible.

The method of production envisages providing a substrate with a first side and a second side. On at least one side of the substrate, conductor patterns are applied without any adhesive. A chip is mounted on one side of the substrate and connected to the conductor patterns. Furthermore, a molding compound is applied on the substrate, so that at least part of the chip and of the conductor patterns is covered.

What is claimed is:

1. A chip card module comprising:
a substrate;
conductor patterns, which are applied on at least one side of the substrate without any adhesive;
a chip, which is arranged on one side of the substrate and connected in an electrically conducting manner to the conductor patterns; and
a mold cap, which encapsulates at least part of the chip and of the conductor patterns.

2. The chip card module as claimed in claim 1, wherein the substrate is flexible.

3. The chip card module as claimed in claim 1, wherein the conductor patterns comprise a sputter layer.

4. The chip card module as claimed in claim 1, wherein the conductor patterns comprise a printed layer.

5. The chip card module as claimed in claim 1, wherein the conductor patterns comprise a metal foil layer.

6. The chip card module as claimed in claim 3, wherein the conductor patterns comprise an electroplated layer.

7. The chip card module as claimed in claim 1, further comprising contact areas which are arranged on one side of the substrate.

8. The chip card module as claimed in claim 1, further comprising a contactless interlace or contacts for connection of a contactless interface.

9. A chip card module comprising:
a flexible substrate;
conductor patterns, which are applied on at least one side of the substrate without any adhesive;
a chip, which is arranged on one side of the substrate and connected in an electrically conducting manner to the conductor patterns; and
a mold cap, which encapsulates the chip and at least part of the conductor patterns.

10. The chip card module as claimed in claim 9, wherein the conductor patterns comprise a starter layer and an electroplated layer applied on the starter layer.

11. The chip card module as claimed in claim 10, wherein the starter layer comprises a sputter layer.

12. The chip card module as claimed in claim 10, wherein the starter layer comprises a printed layer.

13. The chip card module as claimed in claim 10, wherein the starter layer comprises a metal foil layer.

14. The chip card module as claimed in claim 9, wherein the substrate comprises a material selected from the group consisting of polyethylene terephthalate, polyether imide, polyimide and paper.

15. The chip card module as claimed in claim 9, further comprising contact areas which are arranged on one side of the substrate.

16. The chip card module as claimed in claim 9, further comprising a contactless interface or contacts for the connection of a contactless interface.

17. A method of producing a chip card module comprising:
providing a substrate;
applying conductor patterns to at least one side of the substrate without any adhesive;
mounting a chip on one side of the substrate;
connecting the chip to the conductor patterns; and
applying a molding compound to the substrate, so that at least part of the chip and of the conductor patterns is covered.

18. The method as claimed in claim 17, wherein the application of the conductor patterns comprises printing a layer.

19. The method as claimed in claim 18, further comprising electroplating the printed layer.

20. The method as claimed in claim 17, wherein the application of the conductor patterns comprises sputtering a layer.

21. The method as claimed in claim 20, further comprising electroplating the layer.

22. The method as claimed in claim 21, further comprising etching regions of the electroplated layer.

23. The method as claimed in claim 17, wherein the application of the conductor patterns comprises applying a metal foil.

24. The method as claimed in claim 17, further comprising applying contact areas on one side of the substrate.

25. The method as claimed in claim 17, further comprising applying a coupling element or contacts for the connection of a coupling element on the substrate.
